(19) United States
(12) Patent Application Publication
(10) Pub. No.: US 2023/0421965 A1
(43) Pub. Date: Dec. 28, 2023

(54) PIEZOELECTRIC ELEMENT

(71) Applicant: FUJIFILM Corporation, Tokyo (JP)

(72) Inventor: Naohiro OHARA, Minamiashigara-shi (JP)

(73) Assignee: FUJIFILM Corporation, Tokyo (JP)

(21) Appl. No.: 18/461,926

(22) Filed: Sep. 6, 2023

Related U.S. Application Data
(63) Continuation of application No. PCT/JP2022/005416, filed on Feb. 10, 2022.

(30) Foreign Application Priority Data
Mar. 18, 2021 (JP) 2021-045034

(51) Int. Cl. H04R 17/00; H10N 30/85

(52) U.S. Cl. CPC H04R 17/005; H10N 30/852

(57) ABSTRACT

Provided is a piezoelectric element capable of preventing wrinkles from occurring in a piezoelectric element in which a plurality of piezoelectric films are laminated. The piezoelectric element is configured such that a plurality of piezoelectric films, in which a piezoelectric particles in a matrix including a polymer material is sandwiched between electrode layers and a protective layer is laminated on a surface of the electrode layer that is not in contact with the piezoelectric layer, are laminated and the adjacent piezoelectric films are adhered through an adhesive layer. A difference between a maximum height of each piezoelectric film in a thickness direction in a region ranging from an edge surface to 43 μm inside and a height of the piezoelectric film in the thickness direction at a position of 43 μm inside from the edge surface is equal to or less than 4.2 μm.

### CROSS-REFERENCE TO RELATED APPLICATIONS

This application is a Continuation of PCT International Application No. PCT/JP2022/005416 filed on Feb. 10, 2022, which claims priority under 35 U.S.C. § 119(a) to Japanese Patent Application No. 2021-045034 filed on Mar. 18, 2021. The above applications are hereby expressly incorporated by reference, in their entirety, into the present application.

### BACKGROUND OF THE INVENTION

### 1. Field of the Invention

The present invention relates to a piezoelectric element.

### 2. Description of the Related Art

Piezoelectric elements are used in various applications as so-called exciters (exciton) that vibrate articles to generate sound in a case where the elements are adhered in contact with various articles. For example, by adhering an exciter to an image display panel, a screen, or the like and vibrating them, sound can be generated instead of a speaker.

By the way, in a case where an exciter is adhered to a flexible image display device, a rollable screen, or the like, it is necessary for the exciter itself to be flexible (rollable) at least in a case where the exciter is not in use.

As a flexible piezoelectric element, a piezoelectric film in which a piezoelectric layer is sandwiched between an electrode layer and a protective layer has been proposed.

For example, JP2014-209724A describes an electroacoustic conversion film having a piezoelectric laminate, a metal foil for extracting an upper electrode, and a metal foil for extracting a lower electrode. The piezoelectric laminate has a polymer-based piezoelectric composite material that is formed by dispersing piezoelectric particles in a viscoelastic matrix consisting of a polymer material having viscoelasticity at room temperature, an upper thin film electrode that is formed on one surface of the polymer-based piezoelectric composite material and has an area of equal to or less than that of the polymer-based piezoelectric composite material, an upper protective layer that is formed on a surface of the upper thin film electrode and has an area of equal to or greater than that of the upper thin film electrode, a lower thin film electrode that is formed on the opposite surface of the upper thin film electrode of the polymer-based piezoelectric composite material and has an area equal to or less than that of the polymer-based piezoelectric composite material, and a lower protective layer that is formed on the surface of the lower thin film electrode and has an area equal to or larger than that of the lower thin film electrode. The metal foil for extracting the upper electrode is laminated on a part of the upper thin film electrode, and at least a part thereof is located outside the plane direction of the polymer-based piezoelectric composite material. The metal foil for extracting a lower electrode is laminated on a part of the lower thin film electrode, and at least a part thereof is located outside the plane direction of the polymer-based piezoelectric composite material.

Such a piezoelectric film is in the form of a film and has a limited spring constant. Therefore, an output thereof is insufficient in a case where the piezoelectric film is used as an exciter. Therefore, it is conceivable that the spring constant is increased by laminating the piezoelectric film and the output is increased.

### SUMMARY OF THE INVENTION

However, according to the studies of the inventors, the inventors have found that wrinkles may occur in a case where a plurality of piezoelectric films are laminated, resulting in a poor appearance.

An object of the present invention is to solve such a problem of the prior art, and to provide a piezoelectric element capable of preventing wrinkles from occurring in a piezoelectric element in which the plurality of piezoelectric films are laminated.

In order to achieve the above-mentioned object, the present invention has the following configurations.

[1] A piezoelectric element configured such that a plurality of piezoelectric films, in which a piezoelectric particles in a matrix including a polymer material is sandwiched between electrode layers and a protective layer is laminated on a surface of the electrode layer that is not in contact with the piezoelectric layer, are laminated and the adjacent piezoelectric films are adhered through an adhesive layer,

in which a difference between a maximum height of each piezoelectric film in a thickness direction in a region ranging from an edge surface to 43 μm inside and a height of the piezoelectric film in the thickness direction at a position of 43 μm inside from the edge surface is equal to or less than 4.2 μm.

[2] The piezoelectric element according to [1], in which the difference between the maximum height of each piezoelectric film in the thickness direction in the region ranging from the edge surface to 43 μm inside and the height of the piezoelectric film in the thickness direction at the position of 43 μm inside from the edge surface is equal to or less than 1.4 μm.

[3] The piezoelectric element according to [1] or [2], in which the difference between the maximum height of each piezoelectric film in the thickness direction in the region ranging from the edge surface to 43 μm inside and the height of the piezoelectric film in the thickness direction at the position of 43 μm inside from the edge surface is equal to or greater than 0.3 μm.

[4] The piezoelectric element according to any one of [1] to [3], in which a thickness of the piezoelectric film is in a range of 20 μm to 80 μm.

According to the present invention, it is possible to provide a piezoelectric element capable of preventing wrinkles from occurring in a piezoelectric element in which the plurality of piezoelectric films are laminated.

### BRIEF DESCRIPTION OF THE DRAWINGS

FIG. 1 is a diagram schematically showing an example of a piezoelectric element according to an embodiment of the present invention.

FIG. 2 is a cross-sectional view conceptually showing an example of a piezoelectric film included in the piezoelectric element.

FIG. 3 is a partially enlarged view of the vicinity of an edge surface of the piezoelectric film.

FIG. 4 is a diagram schematically showing another example of the piezoelectric element according to the embodiment of the present invention.

FIG. 5 is a diagram schematically showing another example of the piezoelectric element according to the embodiment of the present invention.

FIG. 6 is a conceptual diagram for explaining an example of a production method of the piezoelectric film.

FIG. 7 is a conceptual diagram for explaining an example of the production method of the piezoelectric film.

FIG. 8 is a conceptual diagram for explaining an example of the production method of the piezoelectric film.

FIG. 9 is a side view conceptually showing a cutting device used in the examples.

FIG. 10 is a front view of FIG. 9.

FIG. 11 is a diagram showing an amount of engagement between upper and lower blades of the cutting device of FIG. 9.

FIG. 12 is a side view conceptually showing the cutting device used in the examples.

FIG. 13 is a front view of FIG. 12.

FIG. 14 is a diagram showing an amount of engagement between the upper and lower blades of the cutting device of FIG. 12.

FIG. 15 is a perspective view conceptually showing the cutting device used in the examples.

FIG. 16 is a perspective view conceptually showing the cutting device used in the examples.

FIG. 17 is a top view conceptually showing a punching blade included in the cutting device of FIG. 16.

FIG. 18 is a side view of FIG. 17.

FIG. 19 is a perspective view conceptually showing the cutting device used in the examples.

FIG. 20 is a side view conceptually showing a blade included in the cutting device of FIG. 19.

FIG. 21 is a front view conceptually showing a shape of a blade used in a comparative example.

FIG. 22 is a perspective view of FIG. 21.

### DESCRIPTION OF THE PREFERRED EMBODIMENTS

Hereinafter, a piezoelectric element according to an embodiment of the present invention will be described in detail based on suitable examples shown in the accompanying drawings.

Descriptions of the configuration requirements described below may be made on the basis of representative embodiments of the present invention, but the present invention is not limited to such embodiments.

In the present specification, a numerical range expressed using “to” means a range including numerical values described before and after “to” as a lower limit and an upper limit.

[Piezoelectric Element]

In the piezoelectric element according to the embodiment of the present invention,

The piezoelectric element is configured such that a plurality of piezoelectric films, in which a piezoelectric particles in a matrix including a polymer material is sandwiched between electrode layers and a protective layer is laminated on a surface of the electrode layer that is not in contact with the piezoelectric layer, are laminated and the adjacent piezoelectric films are adhered through an adhesive layer.

A difference between a maximum height of each piezoelectric film in a thickness direction in a region ranging from an edge surface to 43 μm inside and a height of the piezoelectric film in the thickness direction at a position of 43 μm inside from the edge surface is equal to or less than 4.2 μm.

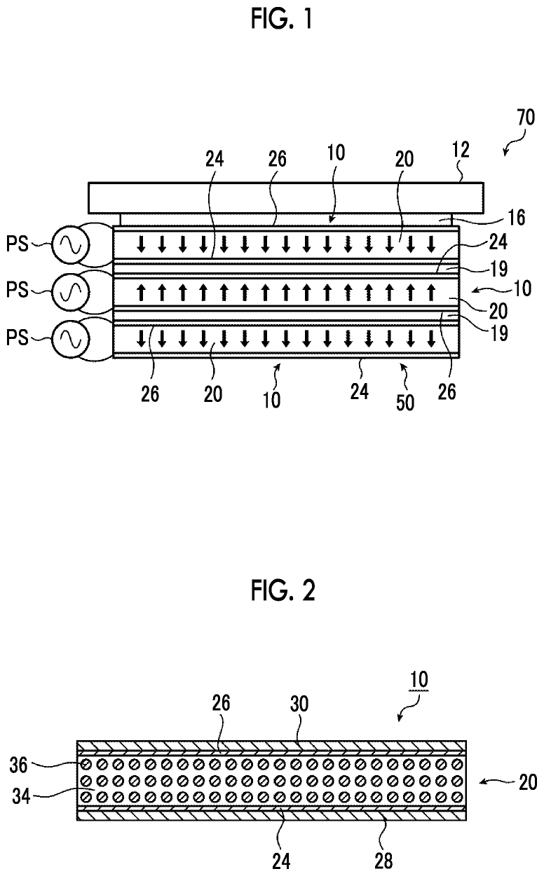

FIG. 1 shows a plan view schematically showing an example of the piezoelectric element according to the embodiment of the present invention.

A piezoelectric element 50 shown in FIG. 1 is formed by laminating a plurality of piezoelectric films 10. In the example shown in FIG. 1, three piezoelectric films 10 are laminated. The adjacent piezoelectric films 10 are adhered to each other through an adhesive layer 19. Further, in the example shown in FIG. 1, the piezoelectric element 50 is adhered to a vibration plate 12 through the adhesive layer 16 to form an electroacoustic transducer 70. A power source PS for applying a driving voltage is connected to each piezoelectric film 10. In the example shown in FIG. 1, a protective layer of each piezoelectric film is not shown. However, as shown in FIG. 2, each piezoelectric film has a protective layer.

In such an electroacoustic transducer 70, in a case where the driving voltage is applied to the piezoelectric film 10 of the piezoelectric element 50, the piezoelectric film 10 stretches and contracts in the plane direction, and the piezoelectric element 50 stretches and contracts in the plane direction due to the stretching and contracting of the piezoelectric film 10.

The stretching and contracting of the piezoelectric element 50 in the plane direction causes the vibration plate 12 to bend, and as a result, the vibration plate 12 vibrates in the thickness direction. The vibration plate 12 generates a sound due to the vibration in the thickness direction. The vibration plate 12 vibrates according to the magnitude of the driving voltage applied to the piezoelectric film 10, and generates a sound according to the driving voltage applied to the piezoelectric film 10.

Consequently, the electroacoustic transducer 70 can be used as a speaker that uses the piezoelectric element 50 as an exciter.

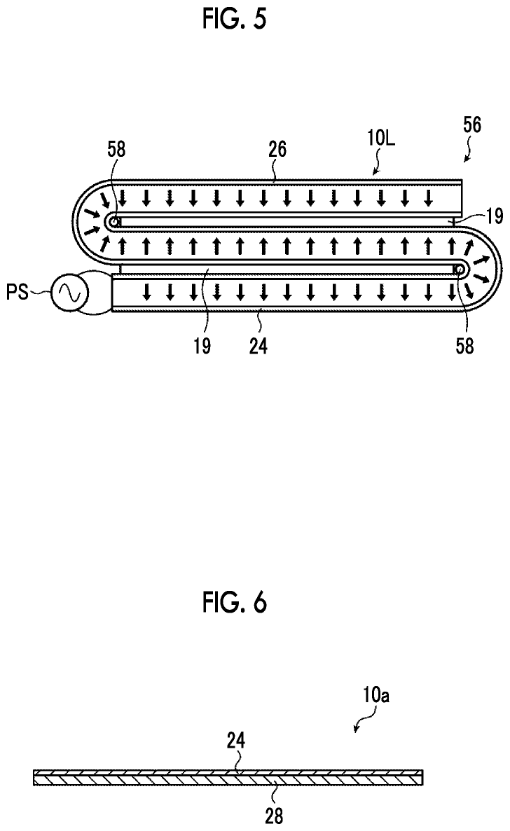

The piezoelectric element 50 shown in FIG. 1 is formed by laminating three piezoelectric films 10, but the present invention is not limited thereto. Consequently, the number of laminated piezoelectric films 10 may be two layers or four or greater layers as long as the piezoelectric element 50 is formed by laminating a plurality of layers of the piezoelectric films 10. From this viewpoint, the same applies to the piezoelectric element 56 shown in FIG. 4 and the piezoelectric element 60 shown in FIG. 5, which will be described later.

In the piezoelectric element 50 shown in FIG. 1, as a preferred embodiment, polarization directions of the adjacent piezoelectric films 10 are opposite to each other. Therefore, in the adjacent piezoelectric films 10, the lower electrode layers 24 face each other and the upper electrode layers 26 face each other. Therefore, the power source PS constantly supplies power of the same polarity to the facing electrodes regardless of whether the power source PS is an alternating-current power source or a direct-current power source. For example, in the piezoelectric element 50 shown in FIG. 1, power of the same polarity is constantly supplied to the upper electrode layer 26 of the piezoelectric film 10 which is the lowermost layer in the drawing and the upper electrode layer 26 of the piezoelectric film 10 which is the second layer (middle layer), and power of the same polarity is constantly supplied to the lower electrode layer 24 of the piezoelectric film 10 which is the second layer and the lower electrode layer 24 of the piezoelectric film 10 which is the uppermost layer in the drawing. Accordingly, in the piezoelectric element 50, even in a case where the electrodes of the adjacent piezoelectric films 10 come into contact with each other, there is no risk of a short circuit.

In the piezoelectric element 50, the polarization direction of the piezoelectric film 10 may be detected by a d33 meter or the like. Alternatively, the polarization direction of the piezoelectric film 10 may be known from the polarization processing conditions to be described below.

FIG. 2 shows an example of the piezoelectric film 10.

The piezoelectric film 10 shown in FIG. 2 includes a piezoelectric layer 20 which is a sheet-like material having piezoelectric properties, the lower electrode layer 24 laminated on one surface of the piezoelectric layer 20, a lower protective layer 28 laminated on a surface of the lower electrode layer 24 opposite to the piezoelectric layer 20, the upper electrode layer 26 laminated on the other surface of the piezoelectric layer 20, and an upper protective layer 30 laminated on a surface of the upper electrode layer 26 opposite to the piezoelectric layer 20. Consequently, the piezoelectric film 10 has a configuration in which the piezoelectric layer 20 is sandwiched between the electrode layers and the protective layer is laminated on a surface of the electrode layer that is not in contact with the piezoelectric layer.

The piezoelectric layer 20 contains piezoelectric particles 36 in a matrix 34 including a polymer material. Further, the lower electrode layer 24 and the upper electrode layer 26 are electrode layers in the embodiment of the present invention. Further, the lower protective layer 28 and the upper protective layer 30 are protective layers in the embodiment of the present invention.

As will be described later, the piezoelectric film 10 (piezoelectric layer 20) is polarized in the thickness direction as a preferred embodiment.

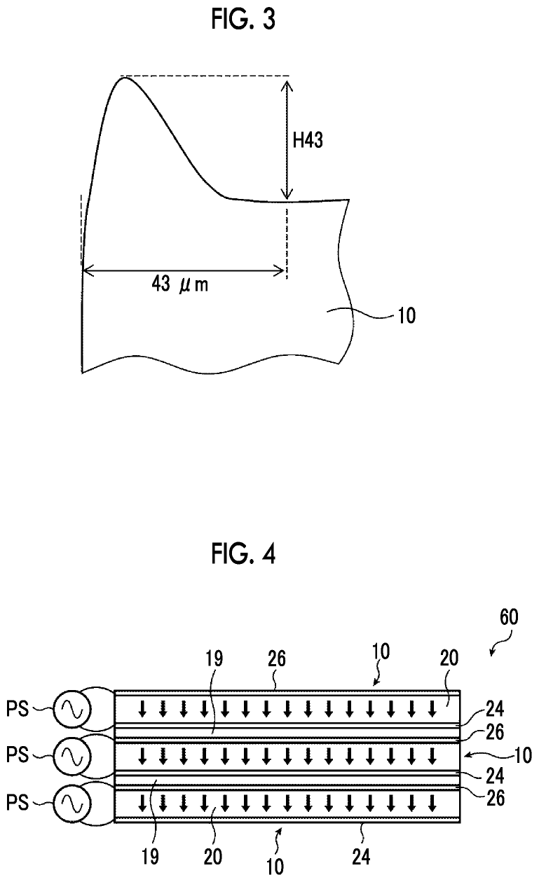

Here, in the embodiment of the present invention, a difference between a maximum height of the piezoelectric film 10 in a thickness direction in a region ranging from an edge surface to 43 μm inside and a height of the piezoelectric film 10 in the thickness direction at a position of 43 μm inside from the edge surface is equal to or less than 4.2 μm. This point will be described using FIG. 3.

FIG. 3 is a partially enlarged view showing a vicinity of an edge surface of the piezoelectric film 10 in an enlarged manner.

As shown in FIG. 3, assuming that the difference between the position of 43 μm inside from the edge surface (side surface) of the piezoelectric film 10 and the maximum height thereof in the region ranging from the edge surface to 43 μm inside is H₄₃, H₄₃ is equal to or less than 4.2 μm.

As described above, in a case where the piezoelectric film in which the piezoelectric layer is sandwiched between the electrode layer and the protective layer is used as an exciter, it is conceivable to laminate the plurality of piezoelectric films in order to compensate for the insufficient output. However, since the piezoelectric film in which the piezoelectric layer is sandwiched between the electrode layer and the protective layer is very thin, wrinkles may occur in a case where the plurality of piezoelectric films are laminated, resulting in a poor appearance.

As a result of an investigation by the present inventor regarding occurrence of such wrinkles, in a case where the piezoelectric film is cut, a projected portion such as a burr may be formed at the end part. Thus, it has been found that in a case where the projected portion is large and a plurality of the piezoelectric films are laminated, an excessive stress is applied to the piezoelectric films, and wrinkles occur.

On the other hand, in the piezoelectric element according to the present invention, the difference H₄₃ between the position of 43 μm inside from the edge surface (side surface) of the piezoelectric film and the maximum height thereof in the region ranging from the edge surface to 43 μm inside is equal to or less than 4.2 μm. In such a case, it can be considered that a height of the projected portion formed on the end part of the piezoelectric film 10 is equal to or less than 4.2 μm.

In such a manner, by setting the height of the projected portion formed on the end part of the piezoelectric film 10 to 4.2 μm or less, it is possible to suppress the application of excessive stress to the piezoelectric film in a case where a plurality of layers of the piezoelectric film are laminated, and it is possible to prevent wrinkles from occurring.

From the viewpoint of preventing wrinkles from occurring, the difference H₄₃ between the position of 43 μm inside from the edge surface of the piezoelectric film and the maximum height thereof in the region ranging from the edge surface to 43 μm inside is preferably 1.4 μm or less, and more preferably 1.0 μm or less.

On the other hand, from the viewpoint of cost, productivity, and the like, H₄₃ is preferably 0.3 μm or more, and more preferably 0.5 μm or more.

The difference H₄₃ between the position of 43 μm inside from the edge surface of the piezoelectric film and the maximum height in the region ranging from the edge surface to 43 m inside is measured as follows.

The piezoelectric film is placed on a flat table, and the surface is scanned from the surface side using a confocal laser scanning microscope to measure the profile of the surface. Thereby, the difference between the position of 43 μm inside from the edge surface of the piezoelectric film and the maximum height in the region ranging from the edge surface in surface profile to 43 μm inside is obtained. Such measurement is performed at 77 points on each side, and the average value thereof is set as H₄₃. Such measurement is performed on both main surfaces.

The piezoelectric film having the difference H₄₃ between the position of 43 μm inside from the edge surface of the piezoelectric film and the maximum height in the region ranging from the edge surface to 43 μm inside within the above range is realized by suitably setting cutting conditions such as a type of a cutting device and a type of a blade, pressing force of the blade, and a cutting speed in a case of cutting the piezoelectric film. Further, even under the same cutting conditions, the height of the projected portion formed in the case of cutting the piezoelectric film changes depending on the state of the blade. For example, in a case where the piezoelectric film is continuously cut using the same blade, a value of H₄₃ in the piezoelectric film which is initially cut is likely to be greater than a value of H₄₃ in the piezoelectric film which is cut after cutting is performed multiple times. Therefore, it is preferable to perform cutting with a favorable state of the blade.

Further, the value of H₄₃ of the piezoelectric film may be set to 4.2 μm or less by subjecting the cut piezoelectric film to the pressure processing with a roller, heat processing, laser processing of the projected portion, or the like.

In the embodiment of the present invention, among the piezoelectric films included in the piezoelectric element, the height difference H₄₃ on the surface facing another piezoelectric film may be equal to or less than 4.2 μm.

Further, as described above, wrinkles in a case where the piezoelectric films are laminated are more likely to occur as the piezoelectric film is thinner. However, since the piezoelectric element according to the embodiment of the present invention can suitably suppress occurrence of wrinkles, a thin piezoelectric film can be used. The thickness of the piezoelectric film is preferably equal to or greater than 20 μm and equal to or less than 80 μm, more preferably equal to or greater than 20 μm and equal to or less than 60 μm, and even more preferably equal to or greater than 20 μm and equal to or less than 50 μm. As will be described in detail later, it is preferable that the electrode layer and the protective layer of the piezoelectric film are thin from the viewpoint of not restricting the stretching and contracting of the piezoelectric layer. On the other hand, it is preferable that the piezoelectric layer has a small voltage (potential difference) required for stretching and contracting the piezoelectric layer by the same amount and is thin from the viewpoint. Consequently, from the viewpoint of large stretching and contracting with a small voltage, it is preferable that the piezoelectric film is thin.

Here, in the example shown in FIG. 1, a configuration is adopted in which the polarization directions of the adjacent piezoelectric films are opposite to each other, but the present invention is not limited thereto. As in the piezoelectric element 60 shown in FIG. 4, the polarization directions of the piezoelectric layers 20 may all be in the same direction.

Further, in the example shown in FIG. 1, a configuration in which a plurality of single-floor piezoelectric films 10 are laminated is not limited thereto.

FIG. 5 shows another example of the piezoelectric element. Since the piezoelectric element 56 shown in FIG. 5 uses a plurality of the same members as those of the piezoelectric element 50 described above, the same members are denoted by the same reference numerals, and the description will be given mainly to different parts.

The piezoelectric element 56 shown in FIG. 5 is formed by lamination of a plurality of piezoelectric films which is performed by folding back a long piezoelectric film 10L once or more, preferably a plurality of times in the longitudinal direction. Further, in the piezoelectric element 56, the piezoelectric film 10L laminated by folding back is adhered through the adhesive layer 19.

By folding back and laminating one long piezoelectric film 10L polarized in the thickness direction, the polarization directions of the piezoelectric film 10L adjacent (facing) in the lamination direction are opposite directions as indicated by the arrows in FIG. 5.

According to such a configuration, the piezoelectric element 56 can be configured with only one long piezoelectric film 10L, only one power source PS for applying the driving voltage is required, and an electrode may be led out from the piezoelectric film 10L at one place.

Therefore, according to the piezoelectric element 56 shown in FIG. 5, the number of components can be reduced, the configuration can be simplified, the reliability of the piezoelectric element (module) can be improved, and a further reduction in cost can be achieved.

Similar to the piezoelectric element 56 shown in FIG. 5, in the piezoelectric element 56 in which the long piezoelectric film 10L is folded back, it is preferable that a core rod 58 is brought into contact with the piezoelectric film 10L and inserted into the folded-back portion of the piezoelectric film 10L.

The lower electrode layer 24 and the upper electrode layer 26 of the piezoelectric film 10L are formed of a metal vapor deposition film or the like. In a case where the metal vapor deposition film is bent at an acute angle, cracks and the like are likely to occur, and thus the electrode may be broken. Consequently, in the piezoelectric element 56 shown in FIG. 5, cracks or the like are likely to occur in the electrodes inside the bent portion.

On the contrary, in the piezoelectric element 56 in which the long piezoelectric film 10L is folded back, by inserting the core rod 58 into the folded-back portion of the piezoelectric film 10L, the lower electrode layer 24 and the upper electrode layer 26 are prevented from being bent. Therefore, occurrence of breakage can be suitably prevented.

Hereinafter, components of the piezoelectric element according to the embodiment of the present invention will be described.

<Piezoelectric Film>

As described above, the piezoelectric film 10 includes a piezoelectric layer 20, the lower electrode layer 24 laminated on one surface of the piezoelectric layer 20, a lower protective layer 28 laminated on a surface of the lower electrode layer 24 opposite to the piezoelectric layer 20, the upper electrode layer 26 laminated on the other surface of the piezoelectric layer 20, and an upper protective layer 30 laminated on a surface of the upper electrode layer 26 opposite to the piezoelectric layer 20.

[Piezoelectric Layer]

The piezoelectric layer 20 may be a layer made of a known piezoelectric material. In the embodiment of the present invention, the piezoelectric layer 20 is preferably a polymer-based piezoelectric composite material in which the piezoelectric particles 36 are included in a matrix 34 including a polymer material.

As the material of the matrix 34 (serving as a matrix and a binder) of the polymer-based piezoelectric composite material constituting the piezoelectric layer 20, a polymer material having viscoelasticity at room temperature is preferably used. Furthermore, in this specification, the “room temperature” indicates a temperature range of approximately 0° C. to 50° C.

Here, it is preferable that the polymer-based piezoelectric composite material (the piezoelectric layer 20) has the following requisites.

(i) Flexibility

For example, in a case of being gripped in a state of being loosely bent with a sense of document such as a newspaper or a magazine as a portable device, the polymer-based piezoelectric composite material is continuously subjected to large bending deformation from the outside at a comparatively slow vibration of equal to or less than a few Hz. At this time, in a case where the polymer-based piezoelectric composite material is rigid, large bending stress is generated to that extent, and a crack is generated at the interface between the polymer matrix and the piezoelectric particles, possibly leading to breakage. Accordingly, the polymer-based piezoelectric composite material is required to have suitable flexibility. Further, in a case where strain energy is diffused into the outside as heat, the stress is able to be relieved. Accordingly, the loss tangent of the polymer-based piezoelectric composite material is required to be suitably large.

As described above, a flexible polymer-based piezoelectric composite material used as an exciter is required to be rigid with respect to vibration of 20 Hz to 20 kHz, and be flexible with respect to vibration of equal to or less than a few Hz. Further, the loss tangent of the polymer-based piezoelectric composite material is required to be suitably large with respect to the vibration of all frequencies of equal to or less than 20 kHz.

Furthermore, it is preferable that the spring constant can be easily adjusted by lamination in accordance with the rigidity (hardness, stiffness, spring constant) of the mating material (vibration plate) to be adhered. In that regard, the thinner the adhesive layer 16 is, the higher energy efficiency can be.

In general, a polymer solid has a viscoelasticity relieving mechanism, and a molecular movement having a large scale is observed as a decrease (relief) in a storage elastic modulus (Young's modulus) or the local maximum (absorption) in a loss elastic modulus along with an increase in a temperature or a decrease in a frequency. Among them, the relief due to a microbrown movement of a molecular chain in an amorphous region is referred to as main dispersion, and an extremely large relieving phenomenon is observed. A temperature at which this main dispersion occurs is a glass transition point (Tg), and the viscoelasticity relieving mechanism is most remarkably observed.

In the polymer-based piezoelectric composite material (the piezoelectric layer 20), the polymer material of which the glass transition point is room temperature, in other words, the polymer material having viscoelasticity at room temperature is used in the matrix, and thus the polymer-based piezoelectric composite material which is rigid with respect to vibration of 20 Hz to 20 kHz and is flexible with respect to vibration of equal to or less than a few Hz is realized. In particular, from a viewpoint of suitably exhibiting such behavior, it is preferable that a polymer material of which the glass transition point at a frequency of 1 Hz is room temperature, that is, equal to or greater than 0° C. and equal to or less than 50° C. is used in the matrix of the polymer-based piezoelectric composite material.

As the polymer material having viscoelasticity at room temperature, various known materials are able to be used. Preferably, a polymer material of which the local maximum value of a loss tangent Tan δ at a frequency of 1 Hz at room temperature, that is, equal to or greater than 0° C. and equal to or less than 50° C. in a dynamic viscoelasticity test is greater than or equal to 0.5 is used.

Accordingly, in a case where the polymer-based piezoelectric composite material is slowly bent due to an external force, stress concentration on the interface between the polymer matrix and the piezoelectric particles at the maximum bending moment portion is relieved, and thus high flexibility is able to be expected.

Further, it is preferable that, in the polymer material having viscoelasticity at room temperature, a storage elastic modulus (E′) at a frequency of 1 Hz in accordance with dynamic viscoelasticity measurement is greater than or equal to 100 MPa at 0° C. and is equal to or less than 10 MPa at 50° C.

Accordingly, it is possible to reduce a bending moment which is generated in a case where the polymer-based piezoelectric composite material is slowly bent due to the external force, and it is possible to make the polymer-based piezoelectric composite material rigid with respect to acoustic vibration of 20 Hz to 20 kHz.

Further, it is more suitable that the relative permittivity of the polymer material having viscoelasticity at room temperature is greater than or equal to 10 at 25° C. Accordingly, in a case where a voltage is applied to the polymer-based piezoelectric composite material, a higher electric field is applied to the piezoelectric particles in the matrix, and thus a large deformation amount can be expected.

However, in consideration of ensuring favorable moisture resistance or the like, it is suitable that the relative permittivity of the polymer material is equal to or less than 10 at 25° C.

As the polymer material having viscoelasticity at room temperature and satisfying such conditions, cyanoethylated polyvinyl alcohol (cyanoethylated PVA), polyvinyl acetate, polyvinylidene chloride-co-acrylonitrile, a polystyrene-vinyl polyisoprene block copolymer, polyvinyl methyl ketone, polybutyl methacrylate, and the like are exemplified. Further, as these polymer materials, a commercially available product such as Hybrar 5127 (manufactured by Kuraray Co., Ltd.) is also able to be suitably used. Among them, as the polymer material, a material having a cyanoethyl group is preferably used, and cyanoethylated PVA is particularly preferably used.

Furthermore, only one of these polymer materials may be used, or a plurality of types thereof may be used in combination (mixture).

The matrix 34 using such a polymer material having viscoelasticity at room temperature, as necessary, may use a plurality of polymer materials in combination.

Consequently, in order to control dielectric properties or mechanical properties, other dielectric polymer materials may be added to the matrix 34 in addition to the viscoelastic material such as cyanoethylated PVA, as necessary.

As the dielectric polymer material which is able to be added to the viscoelastic matrix, for example, a fluorine-based polymer such as polyvinylidene fluoride, a vinylidene fluoride-tetrafluoroethylene copolymer, a vinylidene fluoride-trifluoroethylene copolymer, a polyvinylidene fluoride-trifluoroethylene copolymer, and a polyvinylidene fluoride-tetrafluoroethylene copolymer, a polymer having a cyano group or a cyanoethyl group such as a vinylidene cyanide-vinyl acetate copolymer, cyanoethyl cellulose, cyanoethyl hydroxy saccharose, cyanoethyl hydroxy cellulose, cyanoethyl hydroxy pullulan, cyanoethyl methacrylate, cyanoethyl acrylate, cyanoethyl hydroxy ethyl cellulose, cyanoethyl amylose, cyanoethyl hydroxy propyl cellulose, cyanoethyl dihydroxy propyl cellulose, cyanoethyl hydroxy propyl amylose, cyanoethyl polyacryl amide, cyanoethyl polyacrylate, cyanoethyl pullulan, cyanoethyl polyhydroxy methylene, cyanoethyl glycidol pullulan, cyanoethyl saccharose, and cyanoethyl sorbitol, and a synthetic rubber such as nitrile rubber or chloroprene rubber are exemplified.

Among them, a polymer material having a cyanoethyl group is suitably used.

Furthermore, the dielectric polymer added to the matrix 34 of the piezoelectric layer 20 in addition to the material having viscoelasticity at room temperature such as cyanoethylated PVA is not limited to one dielectric polymer, and a plurality of dielectric polymers may be added.

Further, for the purpose of controlling the glass transition point Tg, a thermoplastic resin such as a vinyl chloride resin, polyethylene, polystyrene, a methacrylic resin, polybutene, and isobutylene, and a thermosetting resin such as a phenol resin, a urea resin, a melamine resin, an alkyd resin, or mica may be added to the matrix 34 in addition to the dielectric polymer.

Further, for the purpose of improving the pressure sensitive adhesiveness, a viscosity imparting agent such as rosin ester, rosin, terpene, terpene phenol, or a petroleum resin may be added.

In the matrix 34 of the piezoelectric layer 20, the addition amount in a case of adding materials other than the polymer material having a viscoelasticity such as cyanoethylated PVA is not particularly limited, but is preferably set to 30% by mass or less in terms of the proportion of the materials in the matrix 34.

Accordingly, it is possible to exhibit properties of the polymer material to be added without impairing the viscoelasticity relieving mechanism of the matrix 34, and thus a preferable result is able to be obtained from a viewpoint of increasing a dielectric constant, of improving heat resistance, and of improving adhesiveness between the piezoelectric particles 36 and the electrode layer.

The piezoelectric layer 20 is a polymer-based piezoelectric composite material in which the piezoelectric particles 36 are included in the matrix 34.

The piezoelectric particles 36 consist of ceramics particles having a perovskite type or wurtzite type crystal structure.

As the ceramics particles forming the piezoelectric particles 36, for example, lead zirconate titanate (PZT), lead lanthanum zirconate titanate (PLZT), barium titanate (BaTiO₃), zinc oxide (ZnO), and a solid solution (BFBT) of barium titanate and bismuth ferrite (BiFe₃) are exemplified.

The particle diameter of the piezoelectric particles 36 is not limited, and may be suitably selected depending on the size of the piezoelectric film 10 and the usage of the piezoelectric element 50. The particle diameter of the piezoelectric particles 36 is preferably equal to or greater than 1 μm and equal to or less than 10 μm.

By setting the particle diameter of the piezoelectric particles 36 to be in this range, it is possible to obtain a preferable result from a viewpoint of allowing the piezoelectric film 10 to achieve both high piezoelectric properties and flexibility.

In addition, in FIG. 2, the piezoelectric particles 36 in the piezoelectric layer 20 are uniformly dispersed in the matrix 34 with regularity. However, the present invention is not limited thereto.

Consequently, in the matrix 34, it is preferable that the piezoelectric particles 36 in the piezoelectric layer 20 are uniformly dispersed, and may also be irregularly dispersed.

In the piezoelectric film 10, a quantitative ratio of the matrix 34 and the piezoelectric particles 36 in the piezoelectric layer 20 is not limited, and may be suitably set in accordance with the size in the plane direction or the thickness of the piezoelectric film 10, the usage of the piezoelectric element 50, properties required for the piezoelectric element 50, and the like.

The volume fraction of the piezoelectric particles 36 in the piezoelectric layer 20 is set to preferably equal to or greater than 30% and equal to or less than 80%, more preferably equal to or greater than 50%, and therefore even more preferably equal to or greater than 50% and equal to or less than 80%.

By setting the quantitative ratio of the matrix 34 and the piezoelectric particles 36 to be in the range described above, it is possible to obtain a preferable result from a viewpoint of achieving high piezoelectric both properties and flexibility.

In the piezoelectric film 10, the thickness of the piezoelectric layer 20 is not particularly limited, and may be suitably set in accordance with the usage of the piezoelectric element 50, the number of laminated piezoelectric films in the piezoelectric element 50, properties required for the piezoelectric film 10, and the like.

The thicker the piezoelectric layer 20, the more advantageous it is in terms of rigidity such as the stiffness of a so-called sheet-like material, but the voltage (potential difference) required to stretch and contract the piezoelectric film 10 by the same amount increases.

The thickness of the piezoelectric layer 20 is preferably equal to or greater than 10 μm and equal to or less than 300 μm, more preferably equal to or greater than 20 μm and equal to or less than 200 μm, and even more preferably equal to or greater than 30 μm and equal to or less than 150 μm.

By setting the thickness of the piezoelectric layer 20 to be in the range described above, it is possible to obtain a preferable result from a viewpoint of compatibility between ensuring the rigidity and suitable flexibility, or the like.

[Electrode Layer and Protective Layer]

As shown in FIG. 2, the piezoelectric film 10 has a configuration in which the lower electrode layer 24 is provided on one surface of the piezoelectric layer 20, the lower protective layer 28 is provided thereon, the upper electrode layer 26 is provided on the other surface of the piezoelectric layer 20, and the upper protective layer 30 is provided thereon. Here, the upper electrode layer 26 and the lower electrode layer 24 form an electrode pair.

That is, the piezoelectric film 10 has a configuration in which both surfaces of the piezoelectric layer 20 are sandwiched between the electrode pair, that is, the lower electrode layer 24 and the upper electrode layer 26 and the laminate is further sandwiched between the lower protective layer 28 and the upper protective layer 30.

As described above, in the piezoelectric film 10, the region sandwiched between the lower electrode layer 24 and the upper electrode layer 26 is stretched and contracted in accordance with an applied voltage.

The lower electrode layer 24 and the lower protective layer 28, and the upper electrode layer 26 and the upper protective layer 30 are denoted in accordance with the polarization direction of the piezoelectric layer 20. Accordingly, the lower electrode layer 24 and the upper electrode layer 26, and the lower protective layer 28 and the upper protective layer 30 have basically the same configuration.

In the piezoelectric film 10, the lower protective layer 28 and the upper protective layer 30 have a function of covering the lower electrode layer 24 and the upper electrode layer 26 and applying suitable rigidity and mechanical strength to the piezoelectric layer 20. That is, the piezoelectric layer 20 consisting of the matrix 34 and the piezoelectric particles 36 in the piezoelectric film 10 exhibits extremely excellent flexibility under bending deformation at a slow vibration, but may have insufficient rigidity or mechanical strength depending on the applications. As a compensation for this, the piezoelectric film 10 is provided with the lower protective layer 28 and the upper protective layer 30.

The lower protective layer 28 and the upper protective layer 30 are not limited, and various sheet-like materials can be used, and suitable examples thereof include various resin films.

Among them, by the reason of excellent mechanical properties and heat resistance, a resin film consisting of polyethylene terephthalate (PET), polypropylene (PP), polystyrene (PS), polycarbonate (PC), polyphenylene sulfide (PPS), polymethyl methacrylate (PMMA), polyetherimide (PEI), polyimide (PI), polyethylene naphthalate (PEN), triacetylcellulose (TAC), or a cyclic olefin-based resin is suitably used.

The thickness of the lower protective layer 28 or the upper protective layer 30 is not limited. Further, the thicknesses of the lower protective layer 28 and the upper protective layer 30 are basically the same as each other, but may be different from each other.

Here, in a case where the rigidity of the lower protective layer 28 and the upper protective layer 30 is extremely high, not only is the stretch and contraction of the piezoelectric layer 20 constrained, but also the flexibility is impaired. Therefore, it is advantageous that the thickness of the lower protective layer 28 and the thickness of the upper protective layer 30 decrease except for the case where the mechanical strength or excellent handleability as a sheet-like material is required.

In a case where the thickness of the lower protective layer 28 and the upper protective layer 30 in the piezoelectric film 10 is two times or less the thickness of the piezoelectric layer 20, preferable results in terms of achieving both ensuring of the rigidity and moderate flexibility can be obtained.

For example, in a case where the thickness of the piezoelectric layer 20 is 50 μm and the lower protective layer 28 and the upper protective layer 30 consist of PET, the thickness of the lower protective layer 28 and the upper protective layer 30 is preferably 100 μm or less, more preferably 50 μm or less, and still more preferably 25 μm or less.

In the piezoelectric film 10, the lower electrode layer 24 is formed between the piezoelectric layer 20 and the lower protective layer 28, and the upper electrode layer 26 is formed between the piezoelectric layer 20 and the upper protective layer 30. The lower electrode layer 24 and the upper electrode layer 26 are provided to apply a voltage to the piezoelectric layer 20 (the piezoelectric film 10).

In the embodiment of the present invention, a forming material of the lower electrode layer 24 and the upper electrode layer 26 is not limited, and as the forming material, various conductive bodies are able to be used. Specifically, metals such as carbon, palladium, iron, tin, aluminum, nickel, platinum, gold, silver, copper, titanium, chromium, and molybdenum, alloys thereof, laminates and composite bodies of these metals and alloys, indium-tin oxide, and the like are exemplified. Among them, copper, aluminum, gold, silver, platinum, and indium-tin oxide are suitably exemplified as the lower electrode layer 24 and the upper electrode layer 26.

Further, a forming method of the lower electrode layer 24 and the upper electrode layer 26 is not limited, and various known methods such as a vapor-phase deposition method (a vacuum film forming method) such as vacuum vapor deposition or sputtering, film formation using plating, and a method of adhering a foil formed of the materials described above are able to be used.

Among them, in particular, by the reason that the flexibility of the piezoelectric film 10 is able to be ensured, a thin film made of copper, aluminum, or the like formed by using the vacuum vapor deposition is suitably used as the lower electrode layer 24 and the upper electrode layer 26. Among them, in particular, the copper thin film formed by using the vacuum vapor deposition is suitably used.

There is no limitation on the thicknesses of the lower electrode layer 24 and the upper electrode layer 26. Further, the thicknesses of the lower electrode layer 24 and the upper electrode layer 26 may basically be identical to each other or different from each other.

Here, similarly to the lower protective layer 28 and upper protective layer 30 mentioned above, in a case where the rigidity of the lower electrode layer 24 and the upper electrode layer 26 is excessively high, not only is the stretching and contracting of the piezoelectric layer 20 constrained, but also the flexibility is impaired. Therefore, there is an advantage in a case where the thicknesses of lower electrode layer 24 and the upper electrode layer 26 are smaller as long as electrical resistance is not excessively high.

In the piezoelectric film 10, in a case where the product of the thicknesses of the lower electrode layer 24 and the upper electrode layer 26 and the Young's modulus is less than the product of the thicknesses of the lower protective layer 28 and the upper protective layer 30 and the Young's modulus, the flexibility is not considerably impaired, which is suitable.

For example, in a case of a combination consisting of the lower protective layer 28 and the upper protective layer 30 formed of PET (Young's modulus: approximately 6.2 GPa) and the lower electrode layer 24 and the upper electrode layer 26 formed of copper (Young's modulus: approximately 130 GPa), in a case where the thickness of the lower protective layer 28 and the upper protective layer 30 is 25 μm, the thickness of the upper electrode layer 26 and the lower electrode layer 24 is preferably equal to or less than 1.2 μm, more preferably equal to or less than 0.3 μm, and particularly preferably equal to or less than 0.1 μm.

As described above, the piezoelectric film 10 has a configuration in which the piezoelectric layer 20 in which the piezoelectric particles 36 are dispersed in the matrix 34 including the polymer material is sandwiched between the lower electrode layer 24 and the upper electrode layer 26 and the laminate is sandwiched between the lower protective layer 28 and the upper protective layer 30.

It is preferable that, in such a piezoelectric film 10, the maximal value of the loss tangent (tan δ) at a frequency of 1 Hz according to dynamic viscoelasticity measurement is present at room temperature and more preferable that the maximal value at which the loss tangent is 0.1 or greater is present at room temperature.

In such a manner, even in a case where the piezoelectric film 10 is subjected to large bending deformation at comparatively a slow vibration of less than or equal to a few Hz from the outside, since the strain energy can be effectively diffused to the outside as heat, occurrence of cracks on the interface between the polymer matrix and the piezoelectric particles can be prevented.

In the piezoelectric film 10, it is preferable that the storage elastic modulus (E′) at a frequency of 1 Hz according to the dynamic viscoelasticity measurement is 10 to 30 GPa at 0° C. and 1 to 10 GPa at 50° C. The same applies to the conditions for the piezoelectric layer 20.

In such a manner, the piezoelectric film 10 may have large frequency dispersion in the storage elastic modulus (E′) at room temperature. That is, the piezoelectric film 10 is able to be rigid with respect to vibration equal to or greater than 20 Hz and equal to or less than 20 kHz, and is able to be flexible with respect to vibration of equal to or less than a few Hz.

Further, in the piezoelectric film 10, it is preferable that the product of the thickness and the storage elastic modulus (E′) at a frequency of 1 Hz in accordance with the dynamic viscoelasticity measurement is 1.0×10⁵ to 2.0×10⁶ N/m at 0° C., and 1.0×10⁵ to 1.0×10⁶ N/m at 50° C. The same applies to the conditions for the piezoelectric layer 20.

In such a manner, the piezoelectric film 10 may have moderate rigidity and mechanical strength within a range not impairing the flexibility and the acoustic properties.

Further, in the piezoelectric film 10, it is preferable that the loss tangent (Tan δ) at a frequency of 1 kHz at 25° C. is 0.05 or greater in a master curve obtained from the dynamic viscoelasticity measurement. The same applies to the conditions for the piezoelectric layer 20.

Accordingly, the frequency properties of a speaker using the piezoelectric film 10 are smoothened, and thus it is also possible to decrease the changed amount of acoustic quality in a case where the lowest resonance frequency f₀ is changed in accordance with a change in the curvature of the speaker.

In addition, in the embodiment of the present invention, the storage elastic modulus (Young's modulus) and the loss tangent of the piezoelectric film 10, the piezoelectric layer 20, and the like may be measured by a known method. For example, the measurement may be performed using a dynamic viscoelasticity measuring device DMS6100 (manufactured by SII Nanotechnique Inc.).

Examples of the measurement conditions include a measurement frequency of 0.1 Hz to 20 Hz (0.1 Hz, 0.2 Hz, 0.5 Hz, 1 Hz, 2 Hz, 5 Hz, 10 Hz, and 20 Hz), a measurement temperature of −50° C. to 150° C., a temperature rising rate of 2° C./min (in a nitrogen atmosphere), a sample size of 40 mm×10 mm (including the clamped region), and a chuck-to-chuck distance of 20 mm.

As shown in FIG. 1, in the piezoelectric element 50, the power source PS for applying the driving voltage for stretching and contracting the piezoelectric film 10, that is, for supplying driving power, is connected to the lower electrode layer 24 and the upper electrode layer 26 of each of the piezoelectric films 10.

The power source PS is not limited and may be a direct-current power source or an alternating-current power source. Further, as for the driving voltage, a driving voltage capable of suitably driving the piezoelectric films 10 may be suitably set in accordance with the thickness, forming material, and the like of the piezoelectric layer 20 of the piezoelectric film 10.

The method of leading out the electrode from the lower electrode layer 24 and the upper electrode layer 26 is not limited, and various known methods can be used.

For example, examples thereof include a method of leading out the electrode to the outside by connecting a conductive body such as a copper foil to the lower electrode layer 24 and the upper electrode layer 26, a method of leading out the electrodes to the outside by forming the through-holes in the lower protective layer 28 and the upper protective layer 30 with a laser or the like and filling the through-holes with a conductive material, and the like.

Examples of the suitable method of leading out the electrode include the method described in JP-A-2014-209724, the method described in JP-A-2016-015354, and the like.

<Adhesive Layer>

In the piezoelectric element, the piezoelectric film is adhered through the adhesive layer 19.

As the adhesive layer 19, various known layers can be used as long as the adjacent piezoelectric films 10 can be adhered to each other.

Accordingly, the adhesive layer 19 may be a layer consisting of an adhesive, which has fluidity during adhering and thereafter is a solid, a layer consisting of a pressure sensitive adhesive which is a gel-like (rubber-like) flexible solid during adhering and does not change in the gel-like state thereafter, or a layer consisting of a material having properties of both an adhesive and a pressure sensitive adhesive.

Here, the piezoelectric element 50 vibrates a vibration plate 12 and generates a sound by stretching and contracting the plurality of laminated piezoelectric films 10. Accordingly, in the piezoelectric element 50, it is preferable that the stretching and contracting of each piezoelectric film 10 is directly transmitted. In a case where a substance having a viscosity that relieves vibration is present between the piezoelectric films 10, the efficiency of transmitting the stretching and contracting energy of the piezoelectric film 10 is lowered, and the driving efficiency of the piezoelectric element 50 is also decreased.

In consideration of this point, it is preferable that the adhesive layer 19 is an adhesive layer consisting of an adhesive from which a solid and hard adhesive layer 19 is obtained, rather than a pressure sensitive adhesive layer consisting of a pressure sensitive adhesive. As a more preferable adhesive layer 19, specifically, an adhesive layer consisting of a thermoplastic type adhesive such as a polyester-based adhesive or a styrene-butadiene rubber (SBR)-based adhesive is suitably exemplified.

Adhesion, unlike pressure sensitive adhesion, is useful in a case where a high adhesion temperature is required. Furthermore, the thermoplastic type adhesive has “comparatively low temperature, short time, and strong adhesion” and is suitable.

The thickness of the adhesive layer 19 is not limited, and a thickness that enables a sufficient adhering force to be exhibited may be suitably set according to the material for forming the adhesive layer 19.

Here, in the piezoelectric element 50 shown in FIG. 1, it is preferable that the thickness of the adhesive layer 19 decreases because the effect of transmitting the stretching and contracting energy of the piezoelectric film 10 increases, and the energy efficiency increases. Further, in a case where the adhesive layer 19 is thick and has high rigidity, there is also a possibility that the stretching and contracting of the piezoelectric film 10 may be constrained.

In consideration of this point, it is preferable that the adhesive layer 19 is thinner than the piezoelectric layer 20. That is, in the piezoelectric element 50, the adhesive layer 19 is preferably hard and thin. Specifically, the thickness of the adhesive layer 19 is preferably in a range of 0.1 to 50 μm, more preferably in a range of 0.1 to 30 μm, and still more preferably in a range of 0.1 to 10 μm in terms of thickness after the adhering.

In addition, in the piezoelectric element 50 shown in FIG. 1, since the polarization directions of the adjacent piezoelectric films are opposite to each other and there is no risk that the adjacent piezoelectric films 10 may be short-circuited, the adhesive layer 19 can be made thin.

In the piezoelectric element, in a case where the spring constant (thickness×Young's modulus) of the adhesive layer 19 is high, there is a possibility that the stretching and contracting of the piezoelectric film 10 may be constrained. Therefore, it is preferable that the spring constant of the adhesive layer 19 is less than or equal to the spring constant of the piezoelectric film 10.

Specifically, the product of the thickness of the adhesive layer 19 and the storage elastic modulus (E′) at a frequency of 1 Hz according to the dynamic viscoelasticity measurement is preferably 2.0×10⁶ N/m or less at 0° C. and 1.0×10⁶ N/m or less at 50° C.

It is preferable that the internal loss of the adhesive layer at a frequency of 1 Hz according to the dynamic viscoelasticity measurement is 1.0 or less at 25° C. in the case of the adhesive layer 19 consisting of a pressure sensitive adhesive, and is 0.1 or less at 25° C. in the case of the adhesive layer 19 consisting of an adhesive.

<Vibration Plate>

In the electroacoustic transducer 70 having the piezoelectric element 50 described above, the vibration plate 12 has flexibility as a preferred embodiment. In the embodiment of the present invention, the expression of “having flexibility” is synonymous with having flexibility in the general interpretation, and indicates being capable of bending and being flexible, specifically, being capable of bending and stretching without causing breakage and damage.

The vibration plate 12 is not limited as long as the vibration plate 12 is preferably flexible, and various sheet-like materials (plate-like material, film) can be used.

Examples of the vibration plate 12 include resin films formed of polyethylene terephthalate (PET), polypropylene (PP), polystyrene (PS), polycarbonate (PC), polyphenylene sulfide (PPS), polymethylmethacrylate (PMMA), and polyetherimide (PEI), polyimide (PI), polyethylene naphthalate (PEN), triacetyl cellulose (TAC), a cyclic olefin-based resin, or the like, foamed plastic formed of foamed polystyrene, foamed styrene, foamed polyethylene, or the like, and various kinds of corrugated cardboard materials obtained by adhering other paperboards to one or both surfaces of wavy paperboards.

Further, in the electroacoustic transducer 70, a display device such as an organic electroluminescence (organic light emitting diode (OLED)) display, a liquid crystal display, a micro light emitting diode (LED) display, and an inorganic electroluminescence display can be suitably used as the vibration plate 12 as long as these have flexibility.

<Adhesive Layer>

In the electroacoustic transducer 70 shown in FIG. 1, as a preferred embodiment, the vibration plate 12 and the piezoelectric element 50 are adhered to each other with the adhesive layer 16.

Various known layers can be used as the adhesive layer 16 as long as the vibration plate 12 and the piezoelectric element 50 can be adhered to each other.

Therefore, the adhesive layer 16 may be a layer consisting of an adhesive, which has fluidity during adhering and thereafter enters a solid state, a layer consisting of a pressure sensitive adhesive, which is a gel-like (rubber-like) flexible solid during adhering and does not change in the gel-like state thereafter, or a layer consisting of a material having properties of both an adhesive and a pressure sensitive adhesive.

Here, in the electroacoustic transducer 70, the piezoelectric element 50 is stretched and contracted to bend and vibrate the vibration plate 12 to generate a sound. Therefore, in the electroacoustic transducer 70, it is preferable that the stretching and contracting of the piezoelectric element 50 is directly transmitted to the vibration plate 12. In a case where a substance having a viscosity that relieves vibration is present between the vibration plate 12 and the piezoelectric element 50, the efficiency of transmitting the stretching and contracting energy of the piezoelectric element 50 to the vibration plate 12 is lowered, and the driving efficiency of the electroacoustic transducer 70 is also decreased.

In consideration of this point, it is preferable that the adhesive layer 16 is an adhesive layer consisting of an adhesive from which a solid and hard adhesive layer 16 is obtained, rather than a pressure sensitive adhesive layer consisting of a pressure sensitive adhesive. As a more preferable adhesive layer 16, specifically, an adhesive layer consisting of a thermoplastic type adhesive such as a polyester-based adhesive or a styrene-butadiene rubber (SBR)-based adhesive is exemplified.

Adhesion, unlike pressure sensitive adhesion, is useful in a case where a high adhesion temperature is required. Furthermore, the thermoplastic type adhesive has “comparatively low temperature, short time, and strong adhesion” and is suitable.

The thickness of the adhesive layer 16 is not limited, and a thickness at which sufficient adhering force (adhesive force or pressure sensitive adhesive force) can be obtained may be suitably set depending on the material of the adhesive layer 16.

Here, in the electroacoustic transducer 70, it is preferable that the thickness of the adhesive layer 16 decreases because the effect of transmitting the stretching and contracting energy (vibration energy) of the piezoelectric element 50 transmitted to the vibration plate 12 increases and the energy efficiency increases. Further, in a case where the adhesive layer 16 is thick and has high rigidity, there is a possibility that the stretching and contracting of the piezoelectric element 50 may be constrained.

In consideration of this point, it is preferable that the adhesive layer 16 is thin. Specifically, the thickness of the adhesive layer 16 is preferably in a range of 0.1 to 50 μm, more preferably in a range of 0.1 to 30 μm, and still more preferably in a range of 0.1 to 10 μm in terms of thickness after adhering.

In the electroacoustic transducer 70, the adhesive layer 16 is provided as a preferred embodiment and is not an essential component.

Therefore, the electroacoustic transducer 70 may fix the vibration plate 12 and the piezoelectric element 50 using a known pressure adhering unit, a fastening unit, a fixing unit, or the like without having the adhesive layer 16. For example, in a case where a shape of the piezoelectric element 50 in a plan view is rectangular, the electroacoustic transducer may be configured by fastening four corners with members such as bolts and nuts, or the electroacoustic transducer may be configured by fastening the four corners and a center portion with members such as bolts and nuts.

However, in such a case, in a case where the driving voltage is applied from the power source PS, the piezoelectric element 50 stretches and contracts independently of the vibration plate 12, and in some cases, only the piezoelectric element 50 bends, and the stretching and contracting of the piezoelectric element 50 is not transmitted to the vibration plate 12. As described above, in a case where the piezoelectric element 50 stretches and contracts independently of the vibration plate 12, the vibration efficiency of the vibration plate 12 due to the piezoelectric element 50 decreases, and thus the vibration plate 12 may not be sufficiently vibrated.

In consideration of this point, it is preferable that the vibration plate 12 and the piezoelectric element 50 are adhered to each other with the adhesive layer 16 as shown in FIG. 1.

As described above, the piezoelectric layer 20 contains the piezoelectric particles 36 in the matrix 34. Further, the lower electrode layer 24 and the upper electrode layer 26 are provided with the piezoelectric layer 20 sandwiched therebetween in the thickness direction.

In a case where a voltage is applied to the lower electrode layer 24 and the upper electrode layer 26 of the piezoelectric film 10 having the piezoelectric layer 20, the piezoelectric particles 36 stretch and contract in the polarization direction according to the applied voltage. As a result, the piezoelectric film 10 (piezoelectric layer 20) contracts in the thickness direction. At the same time, the piezoelectric film 10 stretches and contracts in the in-plane direction due to the Poisson's ratio. The degree of stretching and contracting is equal to or greater than approximately 0.01% and equal to or less than approximately 0.1%.

As described above, the thickness of the piezoelectric layer 20 is preferably equal to or greater than approximately 10 μm and equal to or less than approximately 300 μm. Accordingly, the degree of stretching and contracting in the thickness direction is as extremely small as approximately 0.3 μm at the maximum.

On the contrary, the piezoelectric film 10, that is, the piezoelectric layer 20, has a size much larger than the thickness in the plane direction. Therefore, for example, in a case where the length of the piezoelectric film 10 is 20 cm, the piezoelectric film 10 stretches and contracts by a maximum of approximately 0.2 mm by the application of a voltage.

The vibration plate 12 is adhered to the piezoelectric film 10 through the adhesive layer 16. Accordingly, the stretching and contracting of the piezoelectric film 10 causes the vibration plate 12 to bend, and as a result, the vibration plate 12 vibrates in the thickness direction.

The vibration plate 12 generates a sound due to the vibration in the thickness direction. That is, the vibration plate 12 vibrates according to the magnitude of the voltage (driving voltage) applied to the piezoelectric film 10, and generates a sound according to the driving voltage applied to the piezoelectric film 10.

A general piezoelectric film consisting of a polymer material such as PVDF has in-plane anisotropy in the piezoelectric properties, and has anisotropy in the amount of stretching and contracting in the plane direction in a case where a voltage is applied.

On the other hand, in the piezoelectric element 50 shown in FIG. 1, the piezoelectric film 10 has no in-plane anisotropy in the piezoelectric properties and stretches and contracts isotropically in all directions in the in-plane direction. Consequently, in the piezoelectric element 50 shown in FIG. 1, the piezoelectric film 10 stretches and contracts isotropically and two-dimensionally.

According to such piezoelectric films 10 that stretch and contract isotropically and two-dimensionally, compared to a case where general piezoelectric films formed of PVDF or the like that stretch and contract greatly in only one direction are laminated, the vibration plate 12 can be vibrated with a large force, and a louder and more beautiful sound can be generated.

It should be noted that in FIG. 1, the size of the piezoelectric element 50 in the plane direction is substantially the same as the size of the vibration plate 12 in the plane direction, but the present invention is not limited thereto. For example, the size of the piezoelectric film 50 in the plane direction may be smaller than the size of the vibration plate 12 in the plane direction.

Next, an example of a manufacturing method of the piezoelectric film 10 will be described with reference to FIGS. 6 to 8.

First, as shown in FIG. 6, a sheet-like material 10a is provided in which the lower electrode layer 24 is formed on the lower protective layer 28. The sheet-like material 10a may be produced by forming a copper thin film or the like as the lower electrode layer 24 on the surface of the lower protective layer 28 using vacuum vapor deposition, sputtering, plating, or the like.

In a case where the lower protective layer 28 is extremely thin and thus the handleability is degraded, the lower protective layer 28 with a separator (temporary support) may be used as necessary. Further, a PET having a thickness of 25 μm to 100 μm or the like can be used as the separator. The separator may be removed after thermal compression bonding of the upper electrode layer 26 and the upper protective layer 30 and before laminating any member on the lower protective layer 28.

Meanwhile, the coating material is prepared by dissolving a polymer material serving as a material of the matrix in an organic solvent, adding the piezoelectric particles 36 such as PZT particles thereto, and stirring the solution for dispersion.

The organic solvent other than the above-mentioned substances is not limited, and various organic solvents can be used.

In a case where the sheet-like material 10a is provided and the coating material is prepared, the coating material is cast (applied) onto the sheet-like material 10a, and the organic solvent is evaporated and dried. Accordingly, as shown in FIG. 5, a laminate 10b in which the lower electrode layer 24 is provided on the lower protective layer 28 and the piezoelectric layer 20 is formed on the lower electrode layer 24 is produced. The lower electrode layer 24 indicates an electrode on the substrate side in a case where the piezoelectric layer 20 is applied, and does not indicate the vertical positional relationship in the laminate.

A casting method of the coating material is not limited, and all known methods (coating devices) such as a slide coater or a doctor knife can be used.

As described above, in the piezoelectric film 10, in addition to the viscoelastic material such as cyanoethylated PVA, a dielectric polymer material may be added to the matrix 34.

In a case where the polymer material is added to the matrix 34, the polymer material added to the coating material may be dissolved.

In a case where the laminate 10b in which the lower electrode layer 24 is provided on the lower protective layer 28 and the piezoelectric layer 20 is formed on the lower electrode layer 24 is produced, it is preferable that the piezoelectric layer 20 is subjected to polarization processing (polling).

A polarization processing method of the piezoelectric layer 20 is not limited, and a known method is able to be used.

Before the polarization processing, a calendar processing may be performed to smoothen the surface of the piezoelectric layer 20 using a heating roller or the like. By performing the calendar processing, a thermal compression bonding step described below can be smoothly performed.

In such a manner, while the piezoelectric layer 20 of the laminate 10b is subjected to the polarization processing, a sheet-like material 10c is provided in which the upper electrode layer 26 is formed on the upper protective layer 30. The sheet-like material 10c may be produced by forming a copper thin film or the like as the upper electrode layer 26 on the surface of the upper protective layer 30 using vacuum vapor deposition, sputtering, plating, or the like.

Next, as shown in FIG. 8, the sheet-like material 10c is laminated on the laminate 10b in which the piezoelectric layer 20 is subjected to the polarization processing while the upper electrode layer 26 faces the piezoelectric layer 20.

Further, a laminate of the laminate 10b and the sheet-like material 10c is subjected to the thermal compression bonding using a heating press device, a heating roller pair, or the like such that the upper protective layer 30 and the lower protective layer 28 are sandwiched between the laminate 10b and the sheet-like material 10c.

By the above-mentioned steps, the laminate is produced in which the electrode layer and the protective layer are laminated on both surfaces of the piezoelectric layer 20.

Such a laminate may be manufactured using a sheet-like material in a form of a cut sheet, or may be produced by roll-to-roll (hereinafter, also referred to as RtoR).

The produced laminate is cut into a desired shape in accordance with various uses, and the piezoelectric film can be obtained. In a case of cutting the piezoelectric film, as described above, the difference H₄₃ between the position of 43 μm inside from the edge surface of the piezoelectric film and the maximum height thereof in the region ranging from the edge surface to 43 μm inside may be set to be within the above-mentioned range by suitably setting cutting conditions such as the type of the cutting device, the type of the blade, the pressing force of the blade, and the cutting speed.

The piezoelectric element is produced by laminating the plurality of obtained piezoelectric films through the adhesive layer.

Hereinbefore, the piezoelectric element according to the embodiment of the present invention has been described in detail, but the present invention is not limited to the above-mentioned examples, and various improvements or modifications may be made within a range not departing from the scope of the present invention.

### EXAMPLES

Hereinafter, the present invention will be described in more detail with reference to specific examples of the present invention. It should be noted that the present invention is not limited to the examples, and the materials, the used amounts, the proportions, the processing contents, the processing procedures, and the like shown in the following examples can be suitably changed within a range not departing from the scope of the present invention.

### Example 1

[Production of Piezoelectric Film]

The piezoelectric film shown in FIG. 2 was produced by the method shown in FIGS. 6 to 8 described above.

First, cyanoethylated PVA (CR-V, manufactured by Shin-Etsu Chemical Co., Ltd.) was dissolved in methyl ethyl ketone (MEK) at the following compositional ratio. Thereafter, PZT particles were added to the solution at the following compositional ratio and dispersed using a propeller mixer (rotation speed of 2000 rpm), thereby preparing a coating material for forming a piezoelectric layer.
PZT Particles 1000 parts by mass
Cyanoethylated PVA 100 parts by mass
MEK 600 parts by mass

In addition, as the PZT particles, PZT particles obtained by sintering commercially available PZT raw material powder at 1000° C. to 1200° C. and thereafter crushing and classifying the sintered powder so as to have an average particle diameter of 3.5 μm were used.

On the other hand, a sheet-like material in which a copper thin film having a thickness of 0.1 μm was vacuum vapor deposited on a long PET film having a width of 23 cm and a thickness of 4 μm as shown in FIG. 6 was prepared. That is, in the present example, the lower electrode layer and the upper electrode layer are copper vapor deposition thin films having a thickness of 0.1 μm, and the lower protective layer and the upper protective layer are PET films having a thickness of 4 μm.

In order to obtain satisfactory handleability during the process, a film with a separator (temporary support PET) having a thickness of 50 μm was used as the PET film, and the separator of each protective layer was removed after the thermal compression bonding of the thin film electrodes and the protective layers.

The coating material for forming the piezoelectric layer prepared as described above was applied onto the lower electrode layer (copper vapor deposition thin film) of the sheet-like material by using a slide coater. The coating material was applied such that the film thickness of the coating film after being dried was 40 μm.

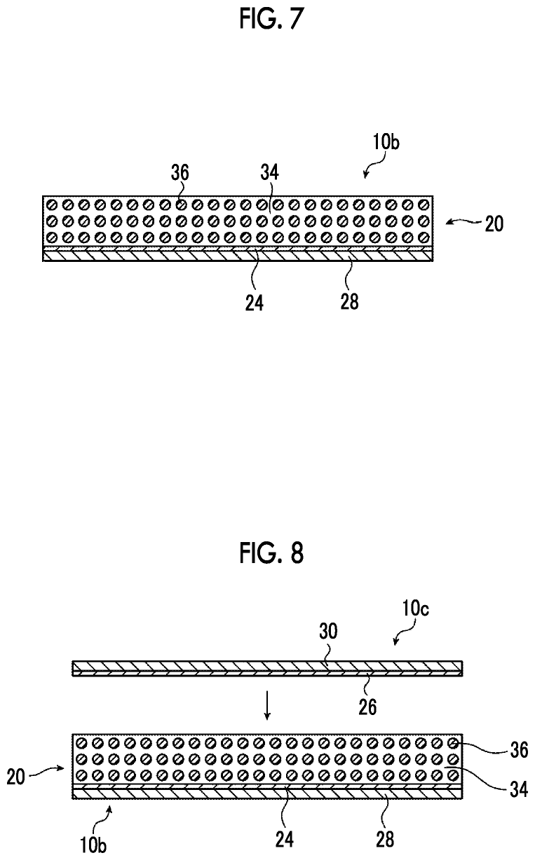

Next, a material in which the coating material was applied onto the sheet-like material was heated and dried in an oven at 120° C. such that MEK was evaporated. Accordingly, as shown in FIG. 7, the laminate was produced in which the lower electrode layer made of copper was provided on the lower protective layer made of PET and the piezoelectric layer having a thickness of 40 μm was formed thereon.

The piezoelectric layer of the laminate was subjected to the polarization processing by a known method. The polarization processing was performed such that the polarization direction was set as the thickness direction of the piezoelectric layer.

On the laminate subjected to the polarization processing, the same sheet-like material obtained by vacuum vapor depositing a copper thin film on a PET film was laminated as shown in FIG. 8.

Next, the laminate of the laminate and the sheet-like material was thermally pressured and adhered at 120° C. using a laminator device to adhere the piezoelectric layer to the lower electrode layer and the upper electrode layer. Thereby, the piezoelectric layer was sandwiched between the lower electrode layer and the upper electrode layer and the laminate was sandwiched between the lower protective layer and the upper protective layer. In such a manner, the piezoelectric film as shown in FIG. 2 was produced.

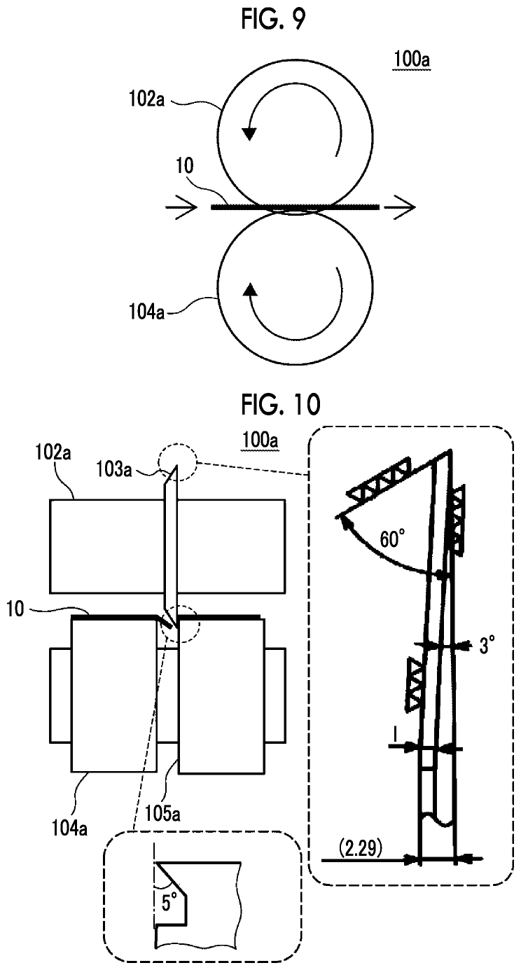

Next, this piezoelectric film was cut into a rectangle having a planar shape of 25×20 cm using the cutting device 100a as shown in FIGS. 9 and 10.

FIG. 9 is a side view conceptually showing the cutting device 100a. FIG. 10 is a front view of FIG. 9.

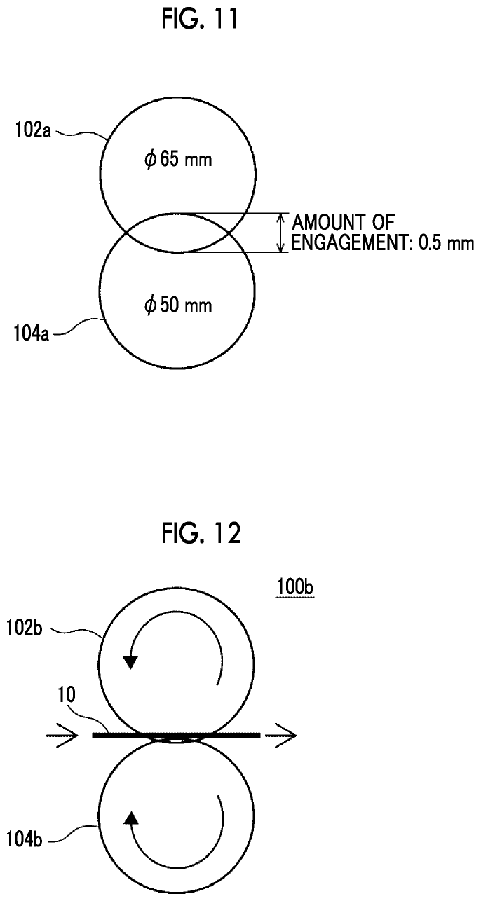

The cutting device 100a shown in FIGS. 9 and 10 is a cutting device using a Goebel round blade, and has an upper blade 102a and a lower blade 104a having a blade on a circumferential surface of a cylindrical drum. The upper blade 102a is provided with the blade 103a so as to be projected in the radial direction from the circumferential surface of the drum. A groove is formed in the circumferential surface of the lower blade 104a of the drum, and a blade 105a is provided at a corner portion of the groove. The upper blade 102a and the lower blade 104a are disposed such that the blades are engaged with each other, and the piezoelectric film 10 is cut by inserting the piezoelectric film 10 between the upper blade 102a and the lower blade 104a. As shown in FIG. 11, an amount of engagement between the upper blade 102a and the lower blade 104a is 0.5 mm. Further, a diameter of the cutting edge of the upper blade 102a is 65 mm. A diameter of the cutting edge of the lower blade 104a is 50 mm.

FIG. 10 shows a shape of the blade 103a of the upper blade 102a and a shape of the blade 105a of the lower blade 104a.

Further, a shaft of the upper blade 102a and a shaft of the lower blade 104a are connected by a belt, and are configured such that, in a case where one blade is rotated, the other blade is also rotated.

The piezoelectric film 10 was inserted between the upper blade 102a and the lower blade 104a of such a cutting device 100a, and the shaft of the lower blade 104a was manually rotated to cut the piezoelectric film 10. Thereby, the piezoelectric film 10 having a size of 25 cm×20 cm was obtained.

The difference H₄₃ between the position of 43 μm inside from the edge surface (side surface) of the piezoelectric film and the maximum height in the region ranging from the edge surface to 43 μm inside was measured by the method described above.

As a result of the measurement, H₄₃ on the front surface side was 0.3 μm, and H₄₃ on the rear surface side was 0.3 μm.

It should be noted that, in a case of cutting the piezoelectric film, a surface on the upper blade 102a side was used as the front surface, and a surface on the lower blade 104a side was used as the rear surface.

This piezoelectric film was folded back four times at intervals of 5 cm in a direction of 25 cm. In the region where the piezoelectric films were laminated, adjacent piezoelectric films were adhered through the adhesive layer. As the adhesive layer, LIOELM TSU0041SI manufactured by Toyochem Co., Ltd. was used. A thickness of the pressure-sensitive adhesive layer after curing was 25 μm.

Accordingly, the piezoelectric film was folded back and five layers were laminated to produce a rectangular piezoelectric element having a planar shape of 5×20 cm.

### Example 2

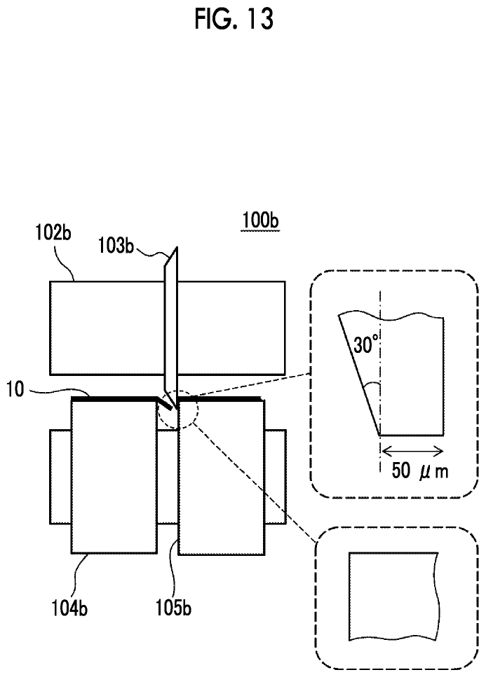

The piezoelectric element was produced in a similar manner to in Example 1 except that a cutting device 100b as shown in FIGS. 12 and 13 was used as the cutting device for cutting the piezoelectric film.

FIG. 12 is a side view conceptually showing the cutting device 100b. FIG. 13 is a front view of FIG. 12.

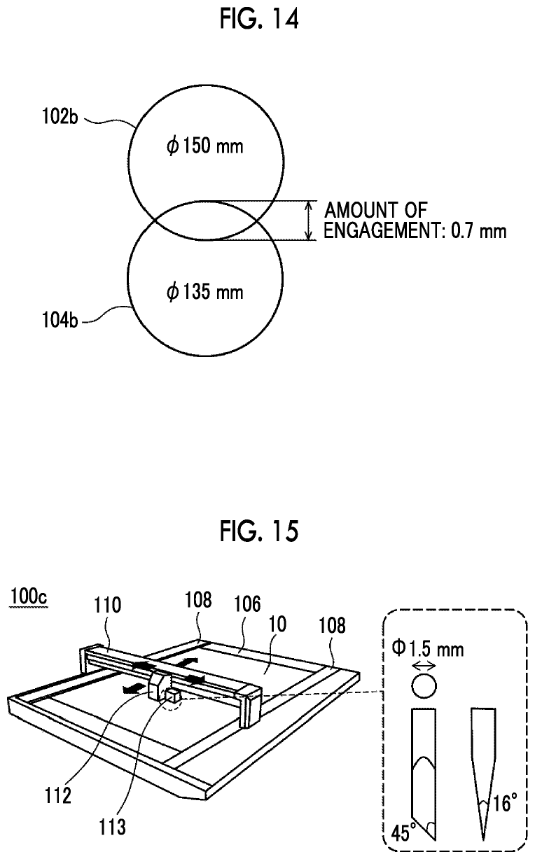

The cutting device 100b shown in FIGS. 12 and 13 is a cutting device using a straight round blade, and has an upper blade 102b and a lower blade 104b having a blade on the circumferential surface of the cylindrical drum. The upper blade 102b is provided with a blade 103b so as to be projected in the radial direction from the circumferential surface of the drum. A groove is formed in the circumferential surface of the lower blade 104b of the drum, and the blade 105b is provided at a corner portion of the groove. The upper blade 102b and the lower blade 104b are disposed such that the blades are engaged with each other, and the piezoelectric film 10 is cut by inserting the piezoelectric film 10 between the upper blade 102b and the lower blade 104b. As shown in FIG. 14, an amount of engagement between the upper blade 102b and the lower blade 104b is 0.7 mm. Further, a diameter of the cutting edge of the upper blade 102b is 150 mm. A diameter of the cutting edge of the lower blade 104b is 135 mm.

FIG. 13 shows a shape of the blade 103b of the upper blade 102b and a shape of the blade 105b of the lower blade 104b.

Further, the shaft of the upper blade 102b and the shaft of the lower blade 104b are connected by a belt, and are configured such that, in a case where one blade is rotated, the other blade is also rotated.

The piezoelectric film 10 was inserted between the upper blade 102b and the lower blade 104b of such a cutting device 100b, and the shaft of the lower blade 104b was manually rotated to cut the piezoelectric film 10. Thereby, the piezoelectric film 10 having a size of 25 cm×20 cm was obtained.

The difference H₄₃ between the position of 43 μm inside from the edge surface (side surface) of the piezoelectric film and the maximum height in the region ranging from the edge surface to 43 μm inside was measured by the method described above. As a result of the measurement, H₄₃ on the front surface side was 0.6 μm, and H₄₃ on the rear surface side was 1.4 μm.

This piezoelectric film was folded back four times at intervals of 5 cm in a direction of 25 cm. In the region where the piezoelectric films were laminated, adjacent piezoelectric films were adhered through the adhesive layer. As the adhesive layer, LIOELM TSU0041SI manufactured by Toyochem Co., Ltd. was used. A thickness of the pressure-sensitive adhesive layer after curing was 25 μm.

Accordingly, the piezoelectric film was folded back and five layers were laminated to produce a rectangular piezoelectric element having a planar shape of 5×20 cm.

### Example 3

The piezoelectric element was produced in a similar manner to in Example 1 except that a cutting device 100c as shown in FIG. 15 was used as the cutting device for cutting the piezoelectric film.

FIG. 15 is a perspective view conceptually showing the cutting device 100c.

As the cutting device 100c, a so-called cutting plotter, FC-4200-60 manufactured by Graphtec Corp., was used. The cutting device 100c has a table 106 on which a member to be cut is placed, two guide portions 108 disposed along two opposite sides of the table 106, an arm part 110, and a head 112.

The arm part 110 extends from one guide portion 108 to the other guide portion 108 and is engaged with the two guide portions 108. The arm part 110 is guided by the two guide portions 108 and is configured to be movable toward the upper side of the table 106, in the extension direction of the guide portion 108 in parallel with the table 106.

The head 112 is configured to be movable in the extension direction of the arm part 110 by being engaged with the arm part 110 and being guided by the arm part 110. Further, the head 112 holds a blade 113, and the cutting edge comes into contact with the cutting member (piezoelectric film 10) placed on the table 106.

In the cutting device 100c, by moving the arm part 110 and the head 112, the blade 113 on the piezoelectric film 10 which is placed on the table 106 is moved to cut the piezoelectric film 10.

As the blade 113, CB15UA (manufactured by Graphtec Corp.) was used. FIG. 15 shows a shape of the blade 113.

The piezoelectric film 10 was cut using such a cutting device 100c to obtain the piezoelectric film 10 having a size of 25 cm×20 cm.

The difference H₄₃ between the position of 43 μm inside from the edge surface (side surface) of the piezoelectric film and the maximum height in the region ranging from the edge surface to 43 μm inside was measured by the method described above. As a result of the measurement, H₄₃ on the front surface side was 1.4 μm, and H₄₃ on the rear surface side was 0 μm.

It should be noted, in a case of cutting the piezoelectric film, a surface on the blade 113 side was used as the front surface, and a surface on the table 106 side was used as the rear surface.

This piezoelectric film was folded back four times at intervals of 5 cm in a direction of 25 cm. In the region where the piezoelectric films were laminated, adjacent piezoelectric films were adhered through the adhesive layer. As the adhesive layer, LIOELM TSU0041SI manufactured by Toyochem Co., Ltd. was used. A thickness of the pressure-sensitive adhesive layer after curing was 25 μm.

Accordingly, the piezoelectric film was folded back and five layers were laminated to produce a rectangular piezoelectric element having a planar shape of 5×20 cm.

### Example 4

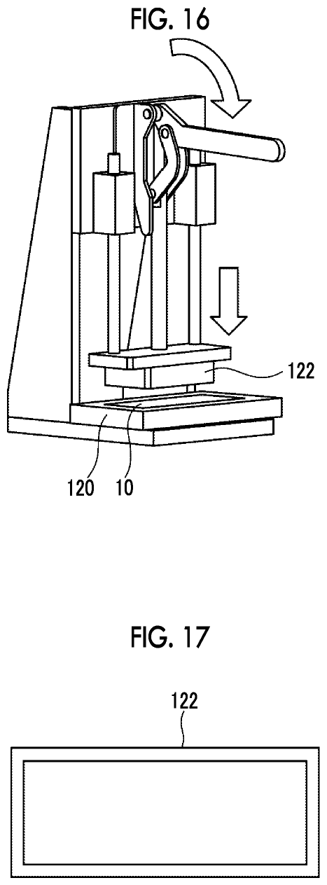

The piezoelectric element was produced in a similar manner to in Example 1 except that a cutting device 100d as shown in FIG. 16 was used as the cutting device for cutting the piezoelectric film.

FIG. 16 is a perspective view conceptually showing the cutting device 100d.

The cutting device 100d shown in FIG. 16 is a cutting device which uses a punching blade (Thomson blade).

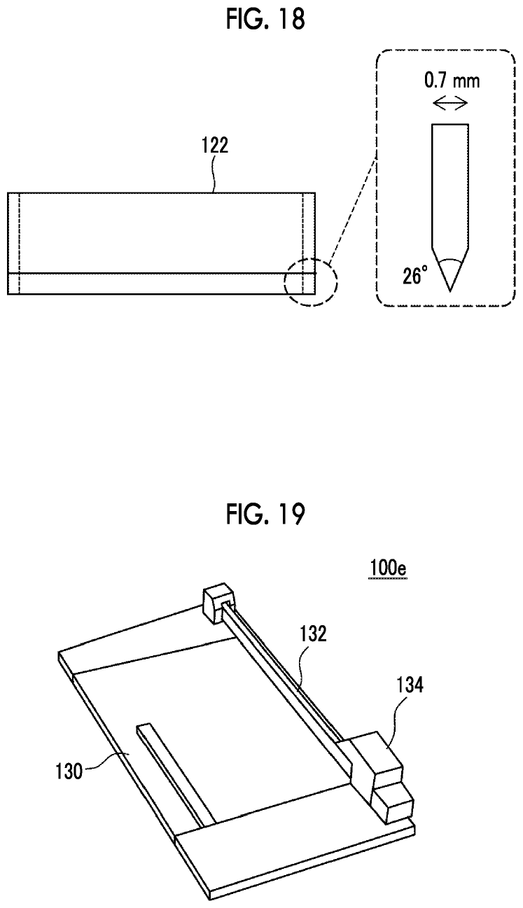

FIG. 17 shows a top view of a punching blade 122, and FIG. 18 shows a side view of FIG. 17.

The cutting device 100d has the punching blade 122 having a rectangular planar shape, and cuts the piezoelectric film 10 into a rectangular shape by pressing the punching blade 122 against the piezoelectric film 10 placed on the table 120 of the cutting device 100d.

FIG. 18 shows a shape of the punching blade 122.

The piezoelectric film 10 was cut using such a cutting device 100d to obtain the piezoelectric film 10 having a size of 25 cm×20 cm.

The difference H₄₃ between the position of 43 μm inside from the edge surface (side surface) of the piezoelectric film and the maximum height in the region ranging from the edge surface to 43 μm inside was measured by the method described above. As a result of the measurement, H₄₃ on the front surface side was 0.5 μm, and H₄₃ on the rear surface side was 4.2 μm.

This piezoelectric film was folded back four times at intervals of 5 cm in a direction of 25 cm. In the region where the piezoelectric films were laminated, adjacent piezoelectric films were adhered through the adhesive layer. As the adhesive layer, LIOELM TSU0041SI manufactured by Toyochem Co., Ltd. was used. A thickness of the pressure-sensitive adhesive layer after curing was 25 μm.

Accordingly, the piezoelectric film was folded back and five layers were laminated to produce a rectangular piezoelectric element having a planar shape of 5×20 cm.

### Comparative Example 1

The piezoelectric element was produced in a similar manner to in Example 1 except that a cutting device 100e as shown in FIG. 19 was used as the cutting device for cutting the piezoelectric film.

FIG. 19 is a perspective view conceptually showing the cutting device 100e.

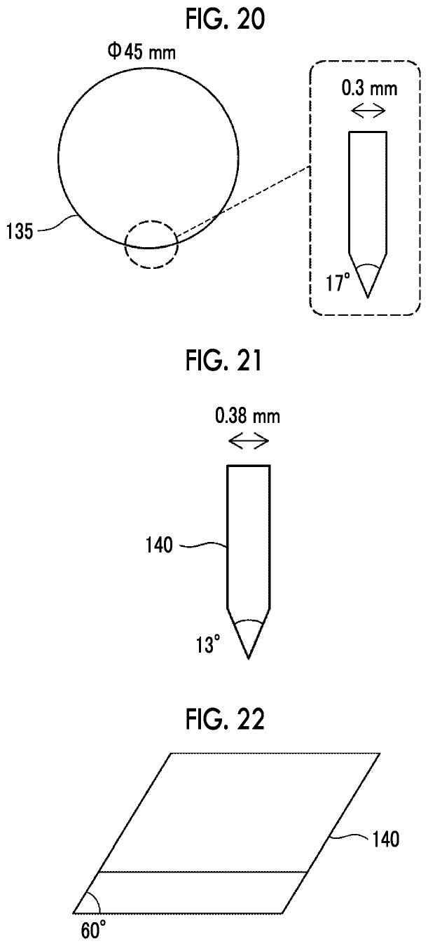

The cutting device 100e is a DN-T61 manufactured by Kokuyo Co., Ltd., and is a cutting device that uses a rotary cutter. The cutting device 100e has a table 130, a guide portion 132 that extends toward the upper side of the table 130 in one direction parallel to the table 130, and a head 134 that is engaged with the guide portion 132 and movable in the extension direction of the guide portion 132. The head 134 has a round blade 135 as shown in FIG. 20, and the round blade 135 rotates with movement of the head 134 to cut a cutting member (piezoelectric film 10) placed on the table 130. As the blade, RB45-1 manufactured by Orfa Corp. was used.

The piezoelectric film 10 was cut using such a cutting device 100e to obtain the piezoelectric film 10 having a size of 25 cm×20 cm.

The difference H₄₃ between the position of 43 μm inside from the edge surface (side surface) of the piezoelectric film and the maximum height in the region ranging from the edge surface to 43 μm inside was measured by the method described above. As a result of the measurement, H₄₃ on the front surface side was 1.9 μm, and H₄₃ on the rear surface side was 8.5 μm.

This piezoelectric film was folded back four times at intervals of 5 cm in a direction of 25 cm. In the region where the piezoelectric films were laminated, adjacent piezoelectric films were adhered through the adhesive layer. As the adhesive layer, LIOELM TSU0041SI manufactured by Toyochem Co., Ltd. was used. A thickness of the pressure-sensitive adhesive layer after curing was 25 μm.

Accordingly, the piezoelectric film was folded back and five layers were laminated to produce a rectangular piezoelectric element having a planar shape of 5×20 cm.

### Comparative Example 2

The piezoelectric element was produced in a similar manner to in Example 1 except that a cutter knife was used as the cutting device for cutting the piezoelectric film. As the cutter knife, XA-1 manufactured by Orfa Corp. was used. Further, SB50K manufactured by Orfa Corp. was used as the blade.

FIG. 21 shows a cross-sectional view of a blade 140 of the cutter knife, and FIG. 22 shows a perspective view of the blade 140 of the cutter knife.

The piezoelectric film 10 was cut using such a cutter knife to obtain the piezoelectric film 10 having a size of 25 cm×20 cm.

The difference H₄₃ between the position of 43 μm inside from the edge surface (side surface) of the piezoelectric film and the maximum height in the region ranging from the edge surface to 43 μm inside was measured by the method described above. As a result of the measurement, H₄₃ on the front surface side was 2.8 μm, and H₄₃ on the rear surface side was 8.7 μm.

This piezoelectric film was folded back four times at intervals of 5 cm in a direction of 25 cm. In the region where the piezoelectric films were laminated, adjacent piezoelectric films were adhered through the adhesive layer. As the adhesive layer, LIOELM TSU0041SI manufactured by Toyochem Co., Ltd. was used. A thickness of the pressure-sensitive adhesive layer after curing was 25 μm.

Accordingly, the piezoelectric film was folded back and five layers were laminated to produce a rectangular piezoelectric element having a planar shape of 5×20 cm.

[Evaluation]

The front surfaces and the rear surfaces of the produced piezoelectric elements of each of the examples and the comparative examples were visually observed, and presence or absence of wrinkles was evaluated in accordance with the following criteria.
A: No wrinkles or streaks are observed.
B: Streaks are observed substantially parallel to the edges, but no wrinkles are observed.
C: Wrinkles are observed from the end edge toward the inside in the plane direction.

Table 1 shows the results thereof.

TABLE 1

| | | H₄₃ (μm) | | |
|---|---|---|---|---|
| | | Front | Rear | |
| | Types of blades | surface | surface | Evaluation |
| | (cutting devices) | side | side | Wrinkles |
| Example 1 | Goebel round blade | 0.3 | 0.3 | A |
| Example 2 | Straight round blade | 0.6 | 1.4 | A |
| Example 3 | Cutting plotter | 1.4 | 0 | A |
| Example 4 | Thomson blade | 0.5 | 4.2 | B |
| Comparative | Rotary cutter | 1.9 | 8.5 | C |
| example 1 | | | | |
| Comparative | Cutter knife | 2.8 | 8.7 | C |
| example 2 | | | | |

From Table 1, it can be seen that no wrinkles occur in any of the examples of the present invention. On the other hand, in Comparative Examples 1 and 2 in which H₄₃ is greater than 4.2 μm, it can be seen that wrinkles occur at the end parts of the laminated piezoelectric films.

Further, from the comparison between Examples 1 to 3 and Example 4, it can be seen that it is preferable that H₄₃ is equal to or less than 1.4 μm.

### Example 5

Using the same cutting device 100a as in Example 1, five piezoelectric films were cut into a rectangular shape having a planar shape of 5×20 cm, and the five piezoelectric films were laminated with the adhesive layer to produce the piezoelectric element.

The difference H₄₃ between the position of 43 μm inside from the edge surface (side surface) of each piezoelectric film and the maximum height in the region ranging from the edge surface to 43 μm inside was measured by the method described above.

As a result of the measurement, H₄₃ on the front surface side of the first sheet was 0.3 m, H₄₃ on the rear surface side was 0.3 μm, H₄₃ on the front surface side of the second sheet was 0.3 μm, H₄₃ on the rear surface side was 0.3 μm, H₄₃ on the front surface side of the third sheet was 0.3 μm, and H₄₃ on the rear surface side was 0.3 μm. The H₄₃ on the front surface side of the fourth piezoelectric film was 0.3 μm, and the H₄₃ on the rear surface side was 0.3 μm. The H₄₃ on the front surface side of the fifth piezoelectric film was 0.3 μm, and the H₄₃ on the rear surface side was 0.3 μm.

In addition, in the order of the piezoelectric films, one side thereof in the case of laminating was set as the first piezoelectric film, and the second and third piezoelectric films were sequentially formed from the first piezoelectric film. Further, in cutting the piezoelectric film, a surface on the upper blade 102a side was used as a front surface, and a surface on the lower blade 104a side was used as a rear surface.

As a result of visually observing the front surface and the rear surface of the produced piezoelectric element, no wrinkles or streaks were observed.

As can be seen from the above results, the effects of the present invention are obvious.

The piezoelectric element according to the embodiment of the present invention is suitably used as the following, for example: as various sensors such as a sound wave sensor, an ultrasonic wave sensor, a pressure sensor, a tactile sensor, a strain sensor, and a vibration sensor (which are useful particularly for an infrastructure inspection such as crack detection and a manufacturing site inspection such as foreign matter contamination detection); acoustic devices such as microphones, pickups, speakers, and exciters (as specific applications, noise cancellers (used for cars, trains, airplanes, robots, and the like), artificial voice bands, buzzers to prevent pests and beasts from invading, furniture, wallpaper, photo, helmet, goggles, headrest, signage, robot, and the like are exemplified); haptics used for application to automobiles, smartphones, smart watches, games, and the like; ultrasonic transducers such as ultrasound probe and hydrophones; actuators used for prevention of attachment of water droplets, transportation, agitation, dispersion, polishing, and the like; vibration damping materials (dampers) used for containers, vehicles, buildings, sports equipment such as skis and rackets; and vibration power generator used for application to roads, floors, mattresses, chairs, shoes, tires, wheels, computer keyboards, and the like.

### EXPLANATION OF REFERENCES

10, 10L: piezoelectric film
10a, 10c: sheet-like material
10b: laminate
12: vibration plate
16, 19: adhesive layer
20: piezoelectric layer
24: lower electrode layer
26: upper electrode layer
28: lower protective layer
30: upper protective layer
34: matrix
36: piezoelectric particles
50, 56, 60: piezoelectric element
58: core rod
70: electroacoustic transducer
100a to 100e: cutting device
102a, 102b: upper blade
103a, 103b, 105a, 105b, 113, 140: blade
104a, 104b: lower blade
106, 120, 130: table
108, 132: guide portion
110: arm part
112, 134: head
122: punching blade
135: round blade

What is claimed is:

1. A piezoelectric element configured such that a plurality of piezoelectric films, in which a piezoelectric particles in a matrix including a polymer material is sandwiched between electrode layers and a protective layer is laminated on a surface of the electrode layer that is not in contact with the piezoelectric layer, are laminated and the adjacent piezoelectric films are adhered through an adhesive layer,
wherein a difference between a maximum height of each piezoelectric film in a thickness direction in a region ranging from an edge surface to 43 μm inside and a height of the piezoelectric film in the thickness direction at a position of 43 μm inside from the edge surface is equal to or less than 4.2 μm.

2. The piezoelectric element according to claim 1, wherein the difference between the maximum height of each piezoelectric film in the thickness direction in the region ranging from the edge surface to 43 μm inside and the height of the piezoelectric film in the thickness direction at the position of 43 μm inside from the edge surface is equal to or less than 1.4 μm.

3. The piezoelectric element according to claim 1, wherein the difference between the maximum height of each piezoelectric film in the thickness direction in the region ranging from the edge surface to 43 μm inside and the height of the piezoelectric film in the thickness direction at the position of 43 μm inside from the edge surface is equal to or greater than 0.3 μm.

4. The piezoelectric element according to claim 1, wherein a thickness of the piezoelectric film is in a range of 20 μm to 80 μm.

5. The piezoelectric element according to claim 2, wherein the difference between the maximum height of each piezoelectric film in the thickness direction in the region ranging from the edge surface to 43 μm inside and the height of the piezoelectric film in the thickness direction at the position of 43 μm inside from the edge surface is equal to or greater than 0.3 μm.

6. The piezoelectric element according to claim 2, wherein a thickness of the piezoelectric film is in a range of 20 μm to 80 μm.

7. The piezoelectric element according to claim 3, wherein a thickness of the piezoelectric film is in a range of 20 μm to 80 μm.
